(19) United States
(12) Patent Application Publication
(10) Pub. No.: US 2012/0306320 A1
(43) Pub. Date: Dec. 6, 2012

(54) PIEZOELECTRIC DEVICE AND MANUFACTURING METHOD THEREOF

(75) Inventors: Ryoichi Ichikawa, Saitama (JP); Yoshiaki Amano, Saitama (JP)

(73) Assignee: NIHON DEMPA KOGYO CO., LTD., Tokyo (JP)

(21) Appl. No.: 13/485,922

(22) Filed: Jun. 1, 2012

(30) Foreign Application Priority Data
Jun. 3, 2011 (JP) 2011-124837

(51) Int. Cl. H01L 41/053; B32B 37/12

(52) U.S. Cl. 310/344; 156/64

(57) ABSTRACT

The present disclosure provides the piezoelectric devices in which the bonding condition of devices can be easily observed. The piezoelectric device (100) comprises: a piezoelectric vibrating piece that vibrates when electrically energized; a first plate (110) and a second plate (120) fabricated by transparent materials; and a sealing material (150a) formed in between the first plate and second plate and in periphery of the first plate and second plate, the sealing material having a slit (151b) within the predetermined width (WX, WZ) of the sealing material.

### CROSS-REFERENCE TO RELATED APPLICATION

This application claims priority to and the benefit of Japan Patent Application No. 2011-124837, filed on Jun. 3, 2011, in the Japan Patent Office, the disclosure of which is incorporated herein by reference in its respective entirety.

### FIELD OF THE INVENTION

The present invention relates to the piezoelectric devices and the manufacturing method thereof. Specifically, the present invention relates to the piezoelectric devices and the manufacturing method thereof in which the sealing condition using a sealing material can be detected.

### DESCRIPTION OF THE RELATED ART

In recent years, surface-mountable piezoelectric devices are manufactured and are more miniaturized and thinned. The surface-mountable piezoelectric device comprises a piezoelectric vibrating piece mounted onto a base and a lid is placed on top of the base for airtight sealing. During the bonding of the base and the lid in airtight manner, glass materials are used as a sealing material. Japan Unexamined Patent Application No. 2004-104766 discloses a method for hermetically sealing a base and a lid, both fabricated by ceramics, using a sealing material such as glass material. Also, the piezoelectric device disclosed in Japan Unexamined Patent Application No. 2004-104766 is manufactured individually, and the bonding condition of each piezoelectric device is inspected by performing damaging test.

### RELATED ART

### Patent Reference

[Patent Reference 1] JP 2004-104766

### PROBLEM TO BE SOLVED BY THE INVENTION

Preferably, the bonding condition of each piezoelectric device can be determined easily. Also, to increase the productivity of piezoelectric devices, it is preferred that several hundreds to several thousands of piezoelectric devices are manufactured at a wafer scale. Even if the piezoelectric devices are manufactured at a wafer scale, it is preferred that bonding conditions of each piezoelectric device can be inspected. Therefore, the sealing condition of the piezoelectric devices of Japan Unexamined Patent Application No. 2004-104766 cannot be easily determined.

The present invention provides the piezoelectric devices, in which the devices are manufactured at a wafer scale, and sealing of the piezoelectric devices can be easily observed by inspecting the melting of the sealing material. The present invention also provides the manufacturing method thereof.

### SUMMARY OF THE INVENTION

A first aspect of the present invention is a piezoelectric device. In its first aspect, a piezoelectric device comprises: a piezoelectric vibrating piece that vibrates when being electrically energized; a first plate and a second plate fabricated by transparent materials and storing the piezoelectric vibrating piece; and a sealing material being placed between the first plate and the second plate. The sealing material having a predetermined with and a frame shape, and configured at a periphery of the first plate and the second plate. The sealing material seals the first plate and the second plate. A slit is configured in the sealing material, and the slit is extending along a direction of the predetermined width without completely cutting through the sealing material along the direction of the predetermined width.

A second aspect of the present invention is a piezoelectric device. In its second aspect, a piezoelectric device comprises: a piezoelectric vibrating piece including a piezoelectric vibrating portion that vibrates when being electrically energized and an outer frame surrounding the piezoelectric vibrating portion; a first plate fabricated by transparent materials and bonded to a principal surface of the outer frame of the piezoelectric vibrating piece; and a first sealing material having a frame shape and a predetermined width. The first sealing material is configured at a periphery of and between the first plate and the outer frame. The sealing material seals the first plate and the outer frame. A slit is configured in the sealing material that bonds the first plate and the outer frame. The slit extends along a direction of the predetermined width without completely cutting through the sealing material along the direction of the predetermined width.

A third aspect of the present invention is a piezoelectric device. In its third aspect, the piezoelectric device described in the second aspect further comprises: a second plate fabricated by the transparent materials and bonded to another principal surface of the outer frame of the piezoelectric vibrating piece; and a second sealing material being placed between the second plate and the outer frame. The second sealing material has a frame shape and a predetermined width, and is configured at a periphery of the piezoelectric vibrating piece. The second sealing material seals the second plate and the outer frame. A slit is formed in the second sealing material that bonds the second plate and the outer frame. The slit extends along a direction of the predetermined width without completely cutting through the second sealing material along the direction of the predetermined width.

A fourth aspect of the present invention is a piezoelectric device. In its fourth aspect, in the piezoelectric device described in any one of first to third aspects, the first sealing material is a low-melting-point glass or polyimide resin that melts between 350° C. to 410° C.

A fifth aspect of the present invention is a method for manufacturing a piezoelectric device. In its fifth aspect, a method for manufacturing a piezoelectric device, comprises a step of preparing a piezoelectric vibrating piece that vibrates when being electrically energized; a step of preparing a first plate and a second plate, and the first plate and the second plate are fabricated by transparent materials; a step of applying a sealing material in periphery of the first plate and the second plate in a frame shape having predetermined width. The sealing material having a slit that does not extend through the predetermined width. The method includes a step of bonding the first plate and the second plate together using the sealing material after the applying step, and a step of inspecting the slit by observing the first plate or the second plate after the bonding step.

A sixth aspect of the present invention is a method for manufacturing a piezoelectric device. The sixth aspect depends on the fifth aspect. The step of preparing the first plate and the second plate further comprises: preparing a first wafer having a plurality of first plates and a second wafer having a plurality of second plates; and bonding the first wafer and the second wafer.

A seventh aspect of the present invention is a method for manufacturing a piezoelectric device. In its seventh aspect, a method for manufacturing a piezoelectric device comprises: a step of preparing a piezoelectric vibrating piece having a piezoelectric vibrating portion that vibrates when being electrically energized and an outer frame surrounding the piezoelectric vibrating portion; a step of preparing a first plate, the first plate is fabricated by transparent materials; and a step of applying a first sealing material in periphery of the first plate or the outer frame in a frame shape having predetermined width. The first sealing material having a slit that does not extend through the predetermined width. The method includes a step of bonding a principal surface of the outer frame and the first plate together using the first sealing material after the applying step; and a step of inspecting the slit by observing the first plate or the outer frame after the bonding step.

An eighth aspect of the present invention is a method for manufacturing a piezoelectric device. In its eighth aspect, in a method for manufacturing a piezoelectric device described in the seventh aspect, the step of preparing the piezoelectric vibrating piece includes a step of preparing a piezoelectric wafer having a plurality of piezoelectric vibrating pieces. The step of preparing the first plate includes a step of preparing a first wafer having a plurality of first plates; the bonding step includes a step of bonding the piezoelectric wafer and the first wafer.

A ninth aspect of the present invention is a method for manufacturing a piezoelectric device. In its ninth aspect, the manufacturing method of the piezoelectric devices described in any one of fifth to eighth aspects includes: the step of applying a sealing material having the plurality of slits. Each slit having different width; and the inspecting step inspects the plurality of slits after being pressed and covered during the bonding step.

A tenth aspect of the present invention is a method for manufacturing a piezoelectric device. In its tenth aspect, the manufacturing method of the piezoelectric devices described in any one of fifth to eighth aspects includes: the step of applying a sealing material has the plurality of slits. Each slit having same width; and the inspecting step includes the step of inspecting the plurality of slits after being pressed covered during the bonding step.

An eleventh aspect of the present invention is a method for manufacturing a piezoelectric device. In its eleventh aspect, the manufacturing method of the piezoelectric devices described in any one of fifth to eighth aspects includes: the step of applying a sealing material has the at least one slit to the piezoelectric device. The inspecting step inspects the plurality of slits after being pressed and covered during the bonding step.

A twelfth aspect of the present invention is a method for manufacturing a piezoelectric device. In its twelfth aspect, the manufacturing method of the piezoelectric devices described in any one of fifth to eleventh aspects includes: the step of inspecting the plurality of slits after being pressed and covered during the bonding step and comparing with remaining slit by using an imaging element.

A thirteenth aspect of the present invention is a method for manufacturing a piezoelectric device. In its thirteenth aspect, the manufacturing method of the piezoelectric devices of any one of fifth to twelfth aspect includes the slit formed on at least a portion of the sealing material having the frame shape, the frame shape having four edges and in a predetermined width.

### EFFECTS OF THE INVENTION

According to the piezoelectric device in the present invention and manufacturing method thereof, bonding condition of the piezoelectric device can be easily observed by forming a slit in the sealing material.

### BRIEF DESCRIPTION OF THE DRAWINGS

FIG. 1A is an exploded perspective view of a piezoelectric device 100.

FIG. 1B is a cross-sectional view of FIG. 1A taken along A-A line.

FIG. 2A illustrates a piezoelectric device 100 that is defectively bonded.

FIG. 2B illustrates a piezoelectric device 100 that is appropriately bonded.

FIG. 2C illustrates a piezoelectric device 100 that is excessively bonded.

FIG. 3 is a flow-chart showing a manufacturing steps of the piezoelectric device 100.

FIG. 4 is a plan view of a first wafer W110.

FIG. 5 is a plan view of a second wafer W120.

FIG. 6 is a plan view of the second wafer W120 in which the sealing material 150a is imprinted by screen-printing.

FIG. 7 is a cross-sectional view of the bonded wafer W100 of the first wafer W110 and the second wafer W120.

FIGS. 8A-8C illustrate side views of an individual piezoelectric device 100.

FIG. 9 is a plan view of a piezoelectric device 100 comprising the determination portions 151 on each edge of the sealing material 150b.

FIG. 10 is a plan view of a sealing material 150b.

FIG. 11 is an enlarged plan view of a sealing material 150b.

FIG. 12 is a plan view of the sealing material 150d imprinted by screen-printing.

FIG. 13 is an exploded perspective view of a piezoelectric device 200.

FIG. 14 is a side plan view of a piezoelectric device 200.

FIG. 15 is a flow-chart showing the manufacturing step of the piezoelectric device 200.

FIG. 16 is a plan view of the piezoelectric wafer W230.

FIG. 17 is a plan view of the second wafer W220.

FIG. 18 is a plan view of the first wafer W210.

FIG. 19 is a plan view of the screen-printed sealing material 150e.

### DETAILED DESCRIPTION

Various embodiments of the subject invention are described in detail below, with reference to the accompanying drawings. It will be understood that the scope of the disclosure is not limited to the described embodiments, unless otherwise stated.

### First Embodiment

### <Configuration of the Piezoelectric Device 100>

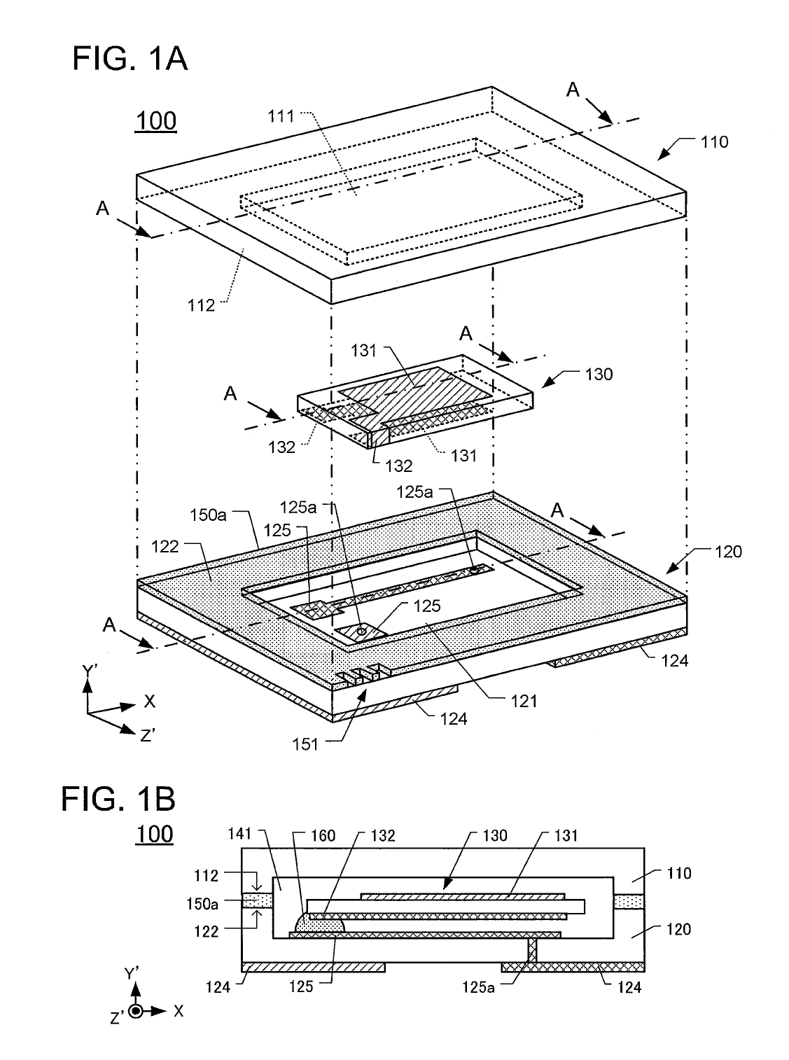

FIG. 1A is an exploded perspective view of a piezoelectric device 100. The piezoelectric device 100 comprises a piezoelectric vibrating piece 130, a first plate (lid) 110 and a second plate (base) 120. In the piezoelectric device 100, non-electrically conductive insulating material, such as crystal, glass or the like, is used as a material of the first plate 110 and the second plate 120. In addition, an AT-cut crystal vibrating piece is used as the piezoelectric vibrating piece 130, for example. An AT-cut quartz-crystal material has a principal surface (in the YZ plane) that is tilted by 35° 15′ about the Y-axis of a crystal-coordinate system (XYZ) in the direction of the Y-axis from the Z-axis around the X-axis. In the following description, new axes tilted with respect to the axial directions of the AT-cut quartz-crystal vibrating piece are denoted as the Y′-axis and Z′-axis, respectively. Therefore, in the quartz-crystal vibrating device, the longitudinal direction of the piezoelectric device is the X-axis direction, the height direction is the Y′-axis direction, and the direction perpendicular to the X-axis and Y′-axis directions is the Z′-axis direction.

In the piezoelectric device 100, the piezoelectric vibrating piece 130 is mounted on the +Y′-axis surface of the second plate 120. Moreover, the piezoelectric device 100 is formed by bonding the first plate 110 on the +Y′-axis side surface of the second plate 120 so as to seal the piezoelectric vibrating piece 130.

The excitation electrodes 131 are situated on both principal surfaces (+Y′-axis and −Y′-axis surfaces) of the piezoelectric vibrating piece 130. The extraction electrodes 132 are extracted from the respective excitation electrodes 131 in the −X-axis direction. The extraction electrode 132 connected to the excitation electrode 131 situated on the −Y′-axis direction is extracted to the −Z′-axis edges on the −X-axis side of the −Y′-axis surface. Also, the extraction electrode 132 connected to the excitation electrode 131 situated on the +Y′-axis surface is extracted to the +Z′-axis edges on the −X-axis side of the −Y′-axis surface. The electrodes, such as the excitation electrodes 131 and extraction electrodes 132 formed on the piezoelectric vibrating piece 130 comprise a chromium layer (Cr) on the piezoelectric vibrating piece 130, followed by overlaying layer of gold (Au).

A recess portion 111 is situated on the −Y′-axis surface of the first plate 110. A bonding surface 112 is formed on the frame shaped periphery of the recess portion 111. The first plate 110 is bonded to the second plate 120 via the bonding surface 112.

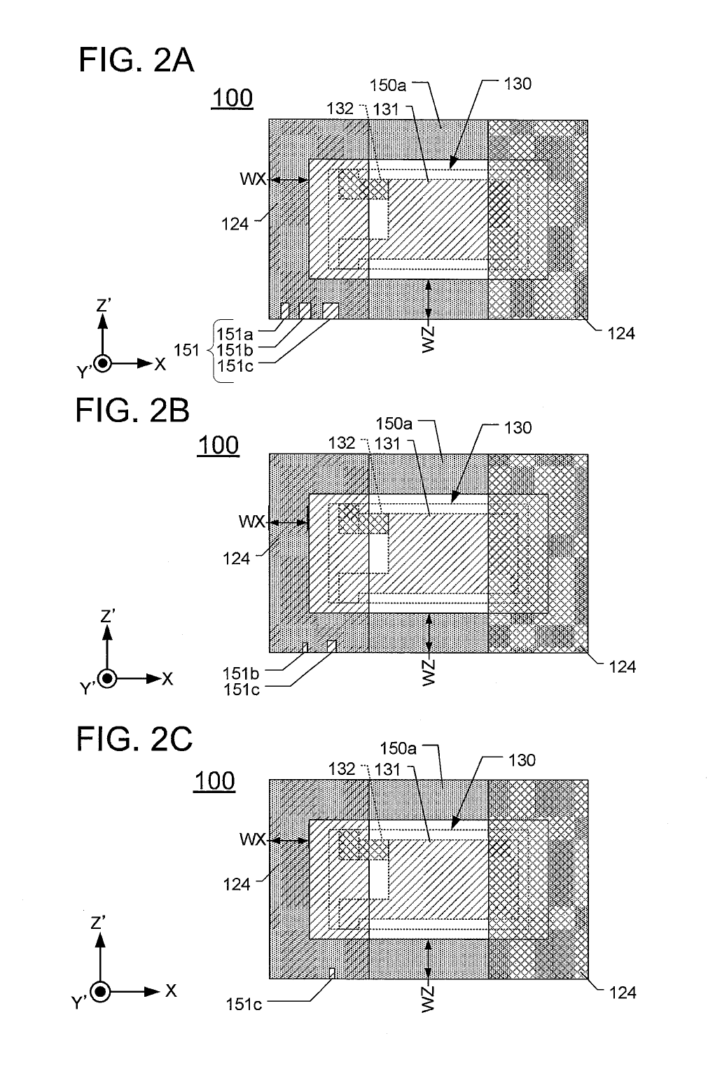

A recess portion 121 is situated on the +Y′-axis surface of the second plate 120. A bonding surface 122 is formed on the frame shaped periphery of the recess portion 121. The bonding surface 122 is formed with the width WX in the X-axis direction and the width WZ in the Z′-axis direction (see FIG. 2A to 2C). On the recess portion 121, a pair of connection electrodes 125 is formed that is electrically connected to the respective extraction electrodes 132 of the piezoelectric vibrating piece 130. A pair of mounting terminals 124 is situated on the −Y′-axis surface of the second plate 120. The pair of connection electrodes 125 and the pair of mounting terminals 124 are electrically connected with each other via a through-hole electrode 125a (see FIG. 1B) that extends through the second plate 120.

A sealing material 150a is applied on the frame shaped bonding surface 122 in a predetermined thickness and width (width WX, WZ) by screen-printing, for example. On a part of the outer edge of the sealing material 150a, a slit-shaped determination portion 151 is formed in a predetermined width, where the sealing material is not applied. In the first embodiment, the determination portion 151 is formed on one edge out of four edges of the frame shaped sealing material 150a. Three slits are formed on each determination portion 151, each slit having different width. Three slits on the determination portion 151 extends depthwise in the Y′-axis direction so that the bonding surface 122 can be viewed, and each slit have different width in the X-axis direction. Also, the determination portion 151 is formed narrower than the width WZ (see FIGS. 2A to 2C) in the Z′-axis direction. If the width of the determination portion 151 and width of the sealing material 150 in the Z′-axis direction are the same, the package cannot be sealed in airtight manner. Also, the sealing material 150a in FIG. 1A is a formation before bonding. Also, the sealing material 150a is drawn so as to show the bottom sides of the sealing material 150a in transparent manner. Details of the sealing material 150a and the determination portion 151 will be explained later.

FIG. 1B is a cross-sectional view of FIG. 1A along A-A line. The bonding surface 112 of the first plate 110 and the bonding surface 122 of the second plate 120 are bonded to each other using a sealing material 150a. The first plate 110 and the second plate 120 bonded together defines a cavity inside the piezoelectric device 100 in airtight manner. The piezoelectric vibrating piece 130 is mounted onto the cavity 141. The respective extraction electrodes 132 on the piezoelectric vibrating piece 130 are electrically connected to the respective connection electrodes 125 via an electrically-conductive adhesive 160. Furthermore, the connection electrodes 125 are electrically connected to the respective mounting terminals 124 via the through-hole electrode 125a that extends through the second plate 120. In other words, the excitation electrodes 131 of the piezoelectric vibrating piece 130 are electrically connected to the respective mounting terminals 124, and the piezoelectric vibrating piece 130 vibrates by applying a voltage between two mounting terminals 124.

The first plate 110 and the second plate 120 are fabricated by transparent materials, such as glass or quartz material. By applying colored sealing material 150a on the piezoelectric device 100, shape of the determination portion 151 of the piezoelectric device 100 can be inspected from outward. Although the sealing material 150a can be semi-transparent or opaque, the embodiment below is explained using the semi-transparent sealing material 150a.

Low-melting-point glass can be used as the sealing material 150a, for example. The low-melting-point glass, for example, melts at a temperature between 350° C.-410° C., which is lower than ordinary glasses. By coloring low-melting-point glass, shape of the determination portion 151 can be easily recognized from outward. When coloring the sealing material 150a, a resin adhesive agent, such as polyimide, can be used, wherein the resin adhesive agent can be colored by mixing with a coloring agent. Although the sealing material 150a is applied onto the bonding surface 122 of the second plate 120, it can be applied onto the first sealing surface 112 of the first plate. Although the low-melting-point glass or resin adhesive can be transparent, it may not be able to be easily detected while observing the determination portion 151.

FIG. 2A-2C is a plan view of the piezoelectric device 100 showing a bonding condition thereof as viewed from the top surface. Also, FIG. 2A-2C is a plan view of the piezoelectric device 100 as viewed from the first plate 110. As shown in FIG. 2A-2C, in the piezoelectric device 100 manufactured by bonding the first plate 110 and the second plate 120, the sealing material 150a, the determination portion 151, the piezoelectric vibrating piece 130, the excitation electrode 131 and the pair of extraction electrodes 132 can be viewed from the first plate 110. Also the mounting terminal 124 can be viewed from the first plate 110 through the semi-transparent sealing material 150a. The determination portion 151 includes a first determination portion 151a, a second determination portion 151b and a third determination portion 151c, each determination portion having different width (slit) in the X-axis direction. The first determination portion 151a has a predetermined width, the second determination portion 151b has a width wider than the predetermined width of the first determination portion 151a, and the third determination portion 151c has a width wider than the width of the second determination portion 151b. The first determination portion 151a, the second determination portion 151b and the third determination portion 151c all have the width narrower than the width WZ (width WZ of the bonding material) of the bonding surface 122.

The first determination portion 151a is mainly used to determine the airtightness of the device, and the second determination portion 151b is mainly used to determine if there is room for airtightness by observing the width after sealing. The third determination portion 151c is mainly used to determine if the heating is too high or the pressure is too high. The predetermined width of the first determination portion 151a is, for example, 20 μm, the second determination portion 151b is, for example, 40 μm and the third determination portion is, for example, 60 μm. Preferably, the widths of the first determination portion 151a to the third determination portion 151c are previously calculated by performing experiments and formed on the screen plate used during the screen-printing.

When bonding the first plate 110 and the second plate 120, the sealing material 150a is heated up to between 350° C. to 410° C., the first plate 110 and second plate 120 are pressed against each other, and then the sealing material 150a between two plates is cooled and hardened. During the bonding process, the piezoelectric device 100 may have a problem with bonding due to the unevenness in the heat distribution, pressing or heating and pressing duration.

FIG. 2A illustrates a piezoelectric device 100 that is defectively bonded. The bonding condition shown in FIG. 2A indicates a situation where the sealing material 150a is not heated adequately, causing the plates being pressed together without melted sealing material 150a, or there is a lack in the pressure although the sealing material is heated adequately. When the first plate 110 and the second plate 120 are bonded defectively, the first determination portion 151a, the second determination portion 151b and the third determination portion 151c can be observed from outward. Thus, in the piezoelectric device 100 with the first determination portion 151a that can be visually observed, the first plate 110 and the second plate 120 are not appropriately sealed, which causes a problem in the airtightness. Therefore, the piezoelectric device 100 in FIG. 2A is inspected as a defective device.

FIG. 2B illustrates a piezoelectric device 100 that is appropriately bonded. In the appropriately bonded piezoelectric device 100, the sealing material 150a is heated and melted at an appropriate temperature, and the first plate 110 and the second plate 120 are pressed against each other with an appropriate pressure. Thus, the melted sealing material 150a covers the first determination portion 151a, which presses and covers the first determination portion 151a entirely. Although the melted sealing material 150a enters into the second determination portion 151b and the third determination portion 151c, the narrowed slit remains and can be observed from outward, due to the width of the slits of the second determination portion 151b and third determination portion 151c are wider in the X-axis direction than the first determination portion 151a. The width of the second determination portion 151b and third determination portion 151c in the Z′-axis direction becomes narrower due to an entrance of the melted sealing material 150a.

FIG. 2C illustrates a piezoelectric device 100 that is excessively bonded. The bonding condition shown in FIG. 2C is caused by pressing together of plates using over-heated sealing material 150a, or with excessive pressure although the sealing material is heated to an appropriate temperature. In the excessively bonded piezoelectric device 100, the melted sealing material 150a covers the slits of the first determination portion 151a and the second determination portion 151b, and the first determination portion 151a and the second determination portion 151b cannot be observed from outward. Out of three determination portions of the piezoelectric device 100, only the third determination portion 151c with narrowed width in the X-axis direction can be observed from outward. Although not drawn, in some cases, the melted sealing material 150a covers the third determination portion 151c. In the piezoelectric device 100 which only the third determination portion 151c can be observed or no determination portion from outward, the sealing material 150a may have entered into the cavity 151. Such piezoelectric device is considered as defective.

### <Manufacturing Method of the Piezoelectric Device 100>

The manufacturing method of the piezoelectric device 100, in which the first plate 110 and the second plate 120 are bonded together using the sealing material 150a, is explained. Although each piezoelectric device can be manufactured individually, the piezoelectric devices 100 are preferably manufactured at wafer scale, each wafer producing several hundreds to several thousands of piezoelectric devices 100. The manufacturing method of a piezoelectric wafer having a plurality of piezoelectric devices 100 is explained hereinbelow.

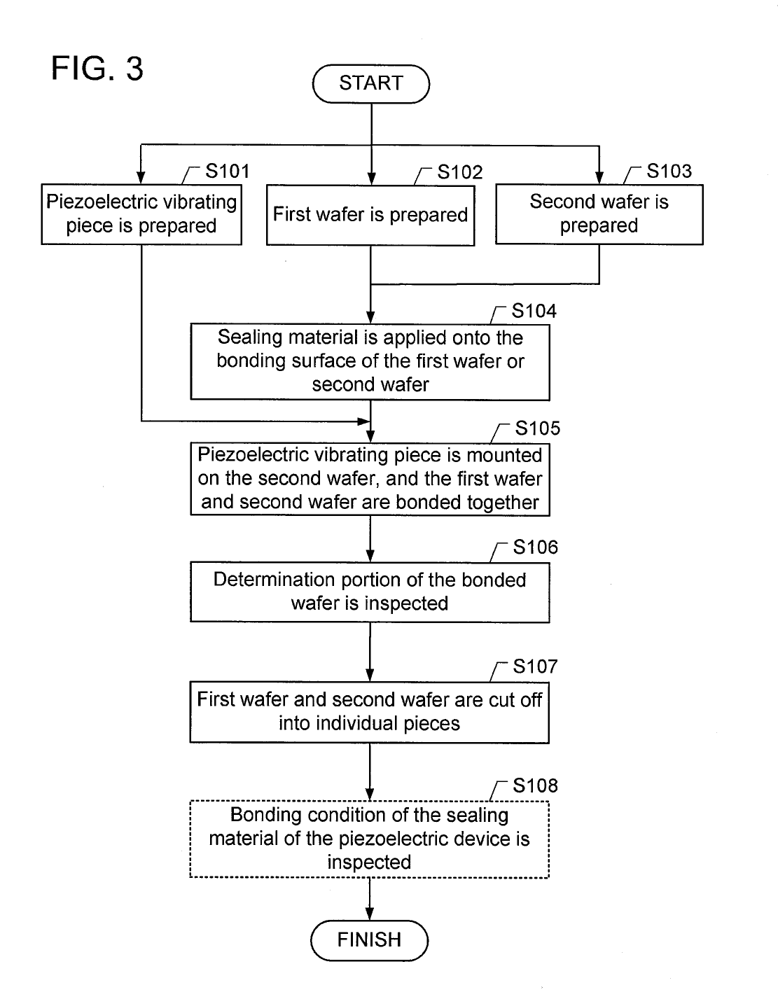

FIG. 3 is a flow-chart showing a manufacturing step of the piezoelectric device 100. First, in Step S101, a plurality of piezoelectric vibrating pieces 130 is prepared. As shown in FIG. 1A, excitation electrodes 131 and extraction electrodes 132 are formed on each piezoelectric vibrating piece 130. Multiple piezoelectric vibrating pieces 130 are manufactured at a wafer scale and each piezoelectric vibrating piece 130 is cut off from the wafer.

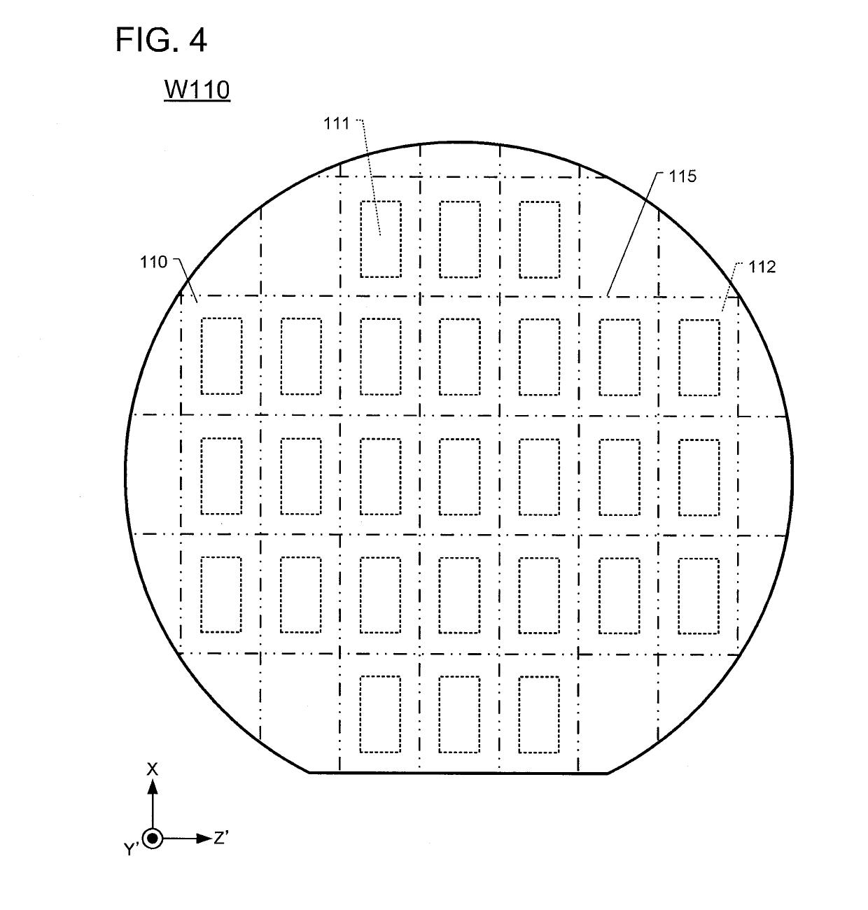

In step S102, a first wafer W110 is prepared. A plurality of first plates 110 is formed on the first wafer W110. The first wafer W110 is formed of transparent materials of, for example, crystal or glass, etc. The first wafer W110 is described with reference to FIG. 4.

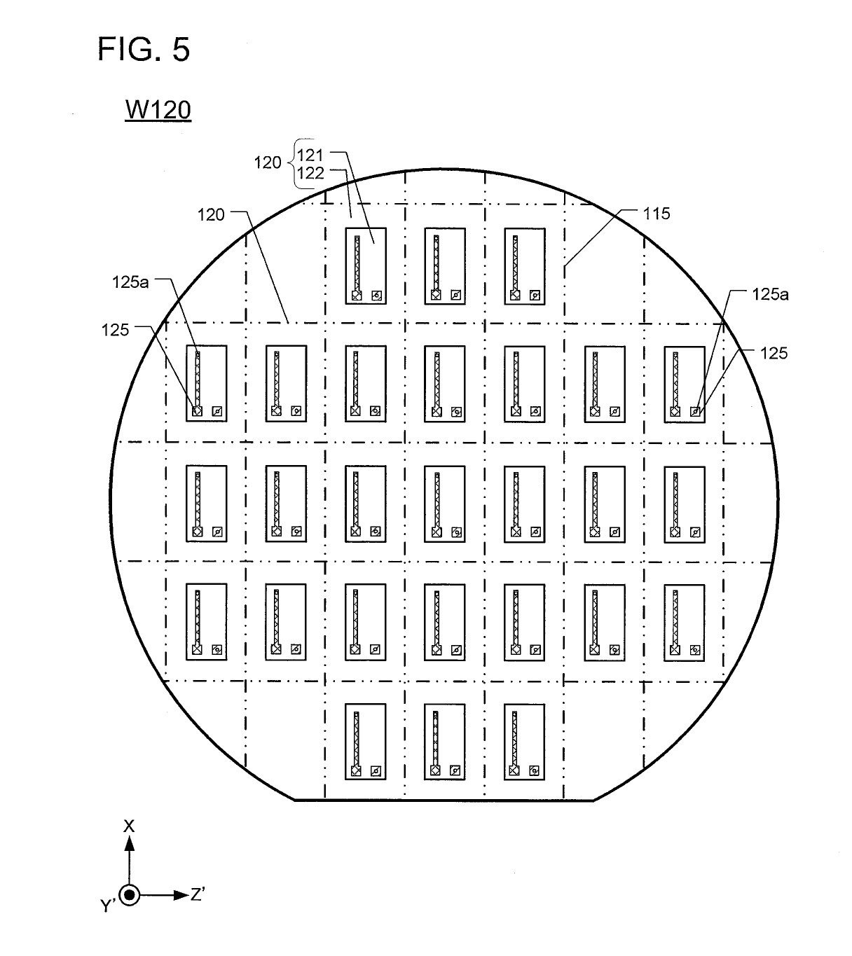

FIG. 4 is a plan view of the first wafer W110. The plurality of first plates 110 is formed on the first wafer W110. In FIG. 4, boundary lines between adjacent first plates 110 are indicated by two-dot dashed lines. The two-dot dashed lines are scribe lines 115 for cutting the wafer in step S107 of FIG. 3, which will be described hereinafter. The respective recess portions 111 are formed on the −Y′-axis surface of each first plate 110, and the frame shaped bonding surfaces 112 are formed in periphery of each recess portion 111, which is to be bonded with a second wafer W120 (see FIG. 5).

In step S103, a second wafer W120 is prepared. A plurality of second plates 120 is formed on the second wafer W120. The second wafer W120 is formed of transparent materials of, for example, crystal or glass, etc. The second wafer W120 is explained using FIG. 5 as reference.

FIG. 5 is a plan view of the second wafer W120. A plurality of second plates 120 is formed on the second wafer W120. Respective recess portions 121 are formed on the +Y′-axis surface of each second plate 120, and the connection electrode 125 and the through-hole electrode 125a are formed on each recess portion 121. Surrounding each recess portion 121, the frame shaped bonding surface 122 is formed. Respective mounting terminals 124 (see FIGS. 1 and 2) are formed on the −Y′-axis surface of the second wafer W120. In FIG. 5, boundary lines between adjacent second plates 120 are indicated by two-dot dashed lines. The two-dot dashed lines are scribe lines 115 for cutting the wafer in step S107 of FIG. 3, which will be explained hereafter. The steps S101 to S103 can be carried out separately or in parallel.

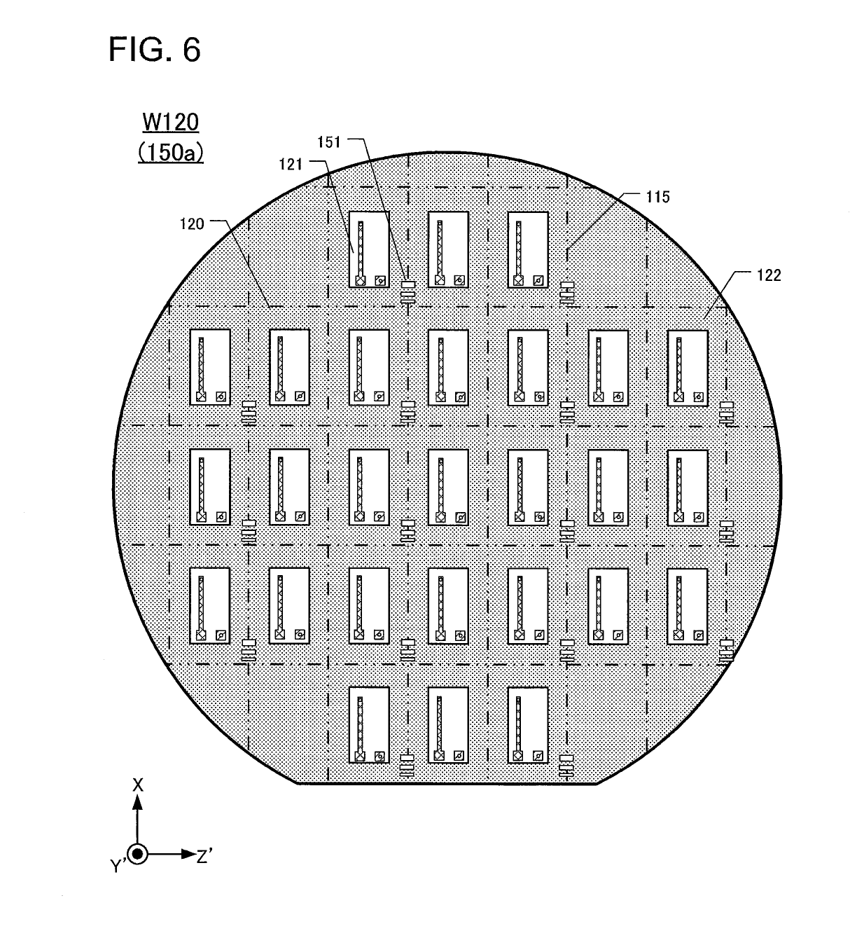

In step S104, the sealing material 150a is imprinted on the first wafer W110 or the second wafer W120 by screen-printing. The sealing material 150a imprinted on the second wafer W120 is explained further in FIG. 6.

FIG. 6 is a plan view of the second wafer W120 in which the sealing material 150a is imprinted on the second wafer W120 by screen-printing. The sealing material 150a is applied onto the bonding surface 122 of the second wafer W120. On the sealing material 150a, the determination portion 151 of three slits is formed on one edge out of four edges of the second plate 120, each slit having different width. FIG. 6 shows one example of the shape of the printed sealing material 150a. By forming the determination portion 151 of the sealing material 150a simultaneously with the adjacent determination portion 151 of the second plate 120, the determination portion 151 is formed on one edge out of four edges of the second plate 120. If the screen-printed sealing material 150a is low-melting-point glass, for example, the low-melting point glass includes the glass element, binder and solvent. The low-melting-point glass is heated until reaches to the evaporation temperature that the binder or solvent evaporates, and then preliminary cured.

Also, in FIG. 6, borderlines of adjacent sealing materials 150a are drawn in the two-dot dashed lines. The two-dot dashed lines are scribe lines 115 for cutting the wafer in Step S107 of FIG. 3, which will be described hereafter. Also, the determination portion 151 can be observed from the side surface of the determination portion 151 in step S108 of FIG. 3, which will be explained hereafter.

In step S105, each piezoelectric device 130 is mounted onto the plurality of recess portions 121 formed on the second wafer W120. Then, the bonding surface 112 of the first wafer W110 and the bonding surface 122 of the second wafer W120 are bonded to each other using the sealing material 150a. During the bonding process, the sealing material 150a is heated to the temperature of, for example, 350° C. to 410° C., pressed against each other with a predetermined pressure and then cooled down. Hereafter, the first wafer W110 and the second wafer W120 bonded together is referred as the bonded wafer W100.

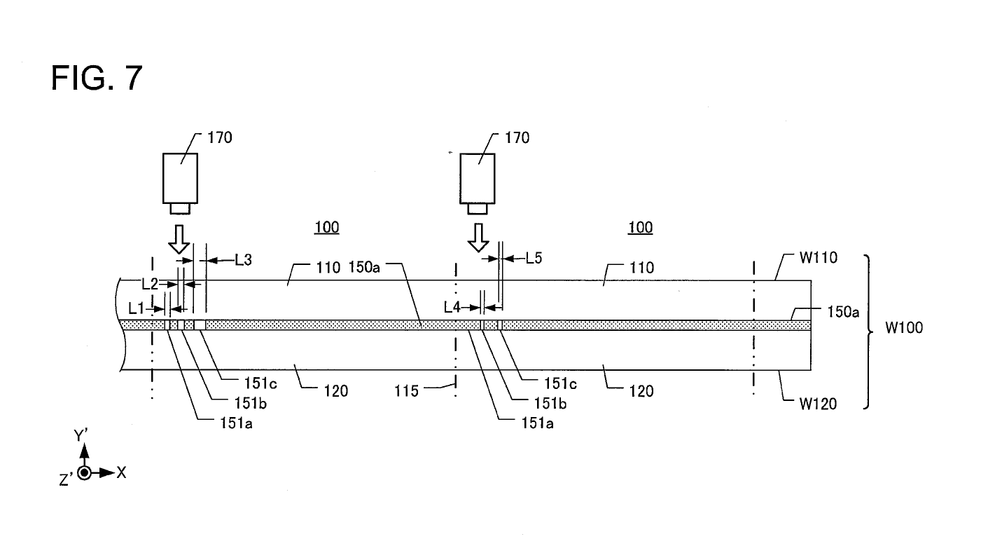

In step S106, the bonding of the sealing material 150a on the bonded wafer W100 is inspected during the observation process. The bonding condition of the sealing material 150a is explained using FIG. 7 as a reference.

FIG. 7 is a cross-sectional view of the bonded wafer W100 after the bonding step. FIG. 7 is a cross-sectional view of the bonded wafer W100 along the scribe line 115 in FIGS. 4, 5 and 6. During the observation process, the bonding condition of the sealing material 150a can be inspected by observing the sealing material 150a from the +Y′-axis surface either visually or by using an imaging element 170. The inspection is preferably performed by irradiating light from the +Y′-axis surface. Additionally, when the imaging element 170 is used for observation, a focal point is fixed to the bonding surface. FIG. 7 illustrates a situation of the imaging element 170 being used to observe the first determination portion 151a, the second determination portion 151b and the third determination portion 151c of the sealing material 150a.

The shape of the determination portion 151, which can be observed visually or by using the imaging element 170, may vary depending on the bonding condition. If the bonding condition is defective, the first determination portion 151a can be observed, as shown in FIG. 2A. On the left side of the piezoelectric device 100 in FIG. 7, the first determination portion 151a is observed as the width L1 of the slit. Similarly, the second determination portion 151b having the width L2 of the slit is observed and the third determination portion 151c having the width L3 of the slit is observed. On the right side of the piezoelectric device 100 in FIG. 7, which is appropriately bonded, the first determination portion 151a is not observable, the slit of the second determination portion 151b having the width L4 of the slit is observed, and the slit of the third determination portion 151c having the width L5 of the slit is observed. Also, an observation of the bonded wafer W100 visually or by using the imaging element 170 not only inspects the shape of the determination portion 151 but also checks whether the bonding surface 112 of the first wafer W110 and the bonding surface 122 of the second wafer W120 are bonded together appropriately. The bonded wafer W100 is bonded in a tilted manner if there is any foreign object between the bonding surfaces 112 and 122 or defect during the bonding process, and as shown in FIG. 7, the piezoelectric device 100 on the right hand side is bonded appropriately although the piezoelectric device 100 on the left hand side is bonded defectively.

Going back to FIG. 3, in step S107, the bonded wafer W100 is cut using dicing saw. The cut is made along the scribe line 115. After the cutting is made, the bonded wafer W100 forms the piezoelectric devices 100 separated in individual pieces.

In step S108, bonding condition of the individual piezoelectric devices 100 is inspected. The bonding condition is inspected by detecting the chipping or bending of the first plate 110 or the second plate 120 during the dicing step in step S107. As explained above, each piezoelectric device 100 is observed visually or using the imaging element 170 from the +Y′-axis surface, or observed by checking the cross-section (Z′-axis side) of the piezoelectric device 100 by dicing. Incidentally, if there is no possibility of having the bonding problem during the dicing process, it is not always necessary to perform the inspection step of step S108. Further, the step S108 can be performed instead of performing the inspection step of step S106.

In the piezoelectric device 100, by coloring the sealing material 150a, the shape of the determination portion 151 and the bonding conditions of the bonding surfaces 112, 122 can be easily observed visually or by using the imaging element 170. Since the piezoelectric device 100 observed from the +Y′-axis surface is explained in FIG. 2, the side surface view (Z′-axis side) of the piezoelectric device 100 is explained.

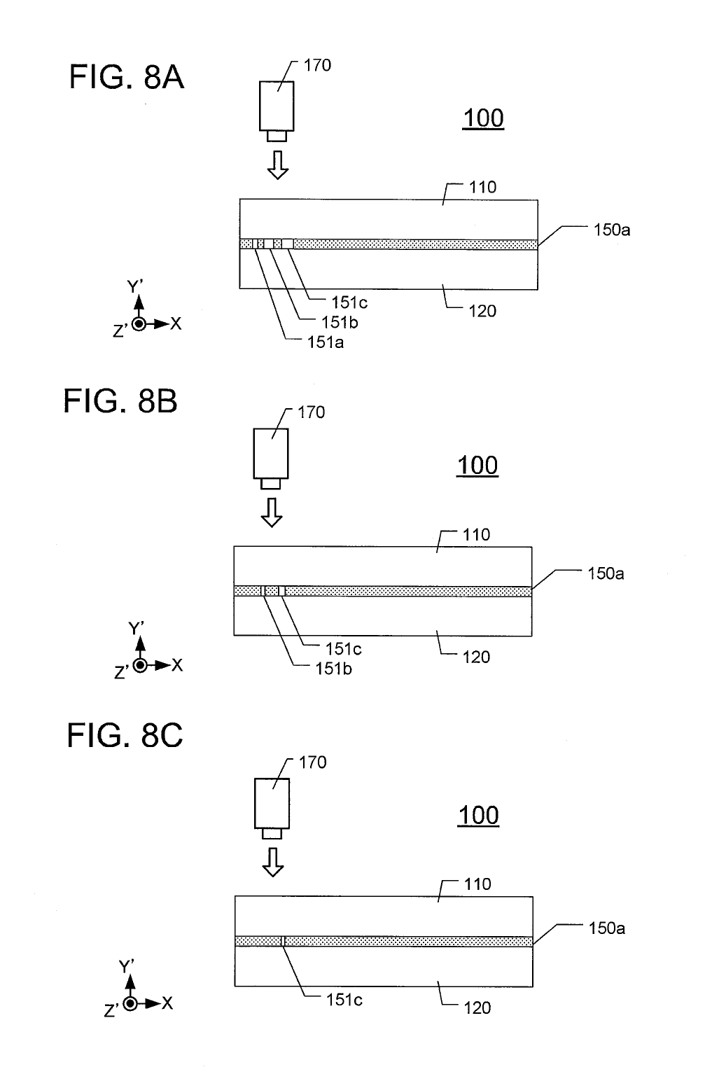

FIGS. 8A-8C are the side views of an individual piezoelectric device 100. FIGS. 8A-8C also illustrate side views of the determination portion 151 of the piezoelectric device 100 separated by the scribe line 115. The piezoelectric device 100 can be observed from the +Y′-axis surface or from the side surface (Z′-axis side) visually or by using the imaging apparatus 170 (not drawn). Since the observation from the +Y′-axis surface is explained in FIGS. 2 and 7, the observation from the side surface (Z′-axis surface) is explained.

FIG. 8 is a side view of the piezoelectric device 100 that is defectively bonded. A problem with bonding the first plate 110 and the second plate 120 is caused by the lack of melting the sealing material 150a, and the second determination portion 151b and the third determination portion 151c are observed from the side surface of the piezoelectric device 100. Thus, the piezoelectric device 100 having the first determination portion 151a that can be observed from the side surface may have a problem with airtightness, and is detected as defective device.

FIG. 8B is a cross-sectional view of the piezoelectric device 100 with appropriate bonding. In the piezoelectric device 100 with appropriate bonding, the melted sealing material 150a covers the entire slit of the first determination portion 151a and the first determination portion 151a cannot be observed from the side surface. In the piezoelectric device 100 with appropriate bonding condition, the second determination portion 151b and the third determination portion 151c can be observed from the side surface.

FIG. 8C shows the piezoelectric device 100 that is excessively bonded. In the piezoelectric device 100 that is excessively bonded, the melted sealing material 150a covers the first determination portion 151a and the second determination portion 151b, and thus makes impossible to observe the first determination portion 151a and the second determination portion 151b. In the piezoelectric device 100 that is excessively bonded, only the third determination portion 151c can be observed from the side surface, and in some cases, the third determination portion 151c cannot be observed. The piezoelectric device 100 in which only the third determination portion 151c can be observed or no determination portion can be observed from the side surface, the sealing material 150a may have entered into the cavity 141, and is detected as defective device. Although the shape of the determination portion 151 is explained in FIG. 8, the bonding problems due to the defective piezoelectric device 100, bending or other problems with bonding can be detected.

The piezoelectric device 100 explained above can be replaced with sealing material 150 having different shapes than above. Hereinafter, the alternatives of the embodiment are explained having different shapes of the sealing material 150. Other configurations are same as the first embodiment, same numberings are used and similar explanations are omitted.

### <Alternative 1>

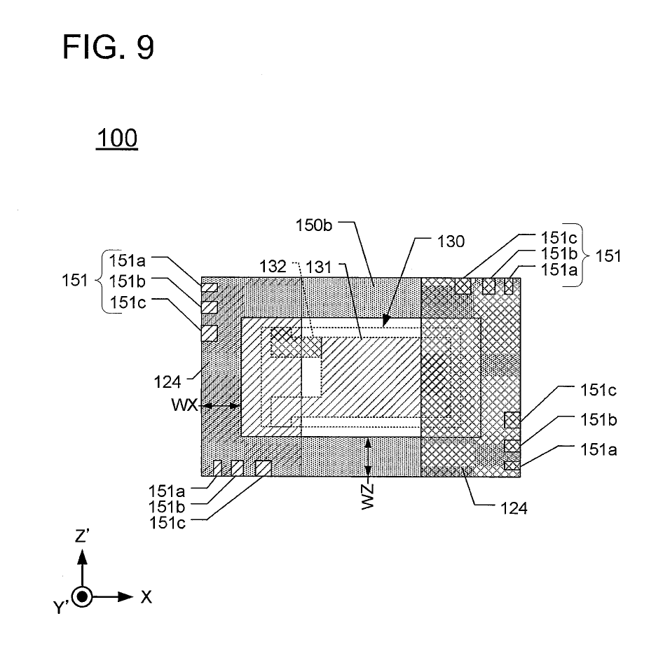

In the sealing material 150b of the first alternative to an embodiment, the determination portions 151 are situated on each edge of the piezoelectric device 100. FIG. 9 illustrates the piezoelectric device having the determination portions 151 on each edge of the sealing material 150b. As explained above, the determination portions 151 are formed on each outer edge of the sealing material 150b, each determination portion 151 comprising the first determination portion 151a, the second determination portion 151b and the third determination portion 151c. The length of a slit of each determination portion 151 aligned in the X-axis direction is shorter than the width WZ of the sealing material 150b in the Z′-axis direction. The length of a slit of each determination portion 151 aligned in the Z′-axis direction is shorter than the width WX of the sealing material 150b in the X-axis direction.

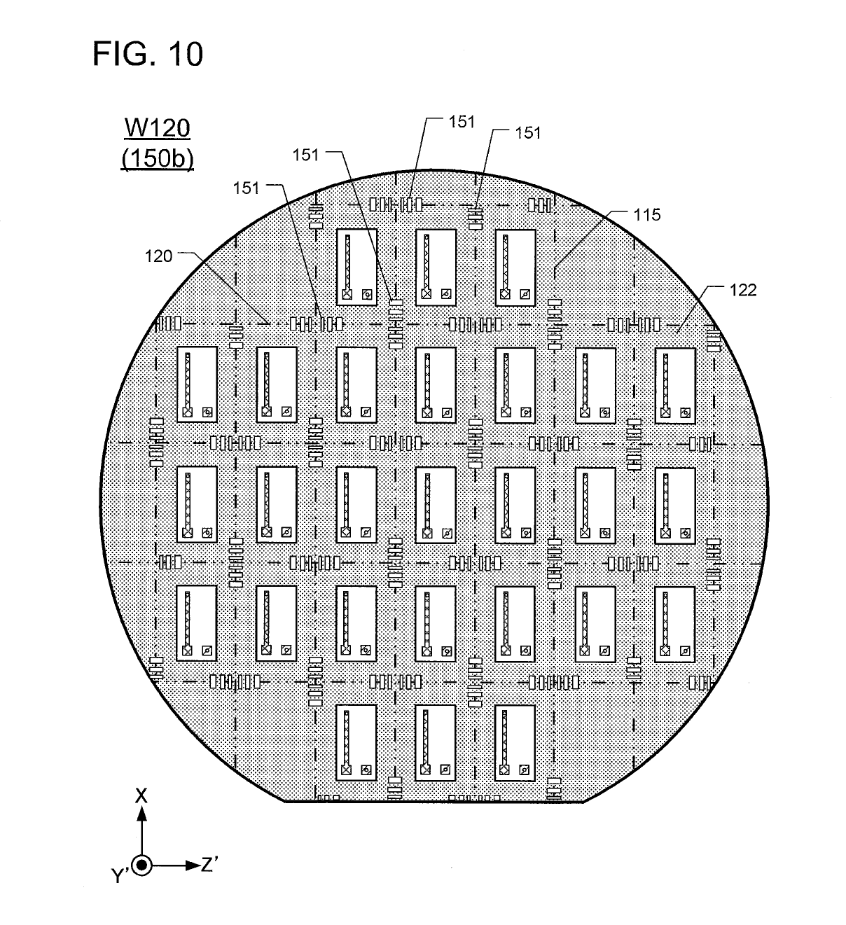

Also, FIG. 10 shows a shape of the sealing material 150b that was imprinted on the second wafer W120 by screen-printing. The sealing material 150b is applied onto the sealing surface 122 of the second wafer W120. The determination portions 151 with each slit thereof having different width are formed on each edge of the sealing material 150 of the second plate 120. FIG. 10 shows an example of a shape of the sealing material 150b. By forming the determination portions 151 simultaneously with adjacent determination portion 151 on the second plate 120, determination portion 151 can be formed on each edge of the second plate 120. In FIG. 10, the boundary line between the adjacent sealing material 150b is shown with two-dot dashed lines. The two-dot dashed lines are also a scribe line 115 that was explained previously. Also, as explained previously, the determination portions 151 can be observed from top surface (facing the first wafer W110) during the bonding step or from the side surface of the determination portion 151 after the dicing step. Also, the sealing material 150b can be imprinted on the bonding surface 112 of the first wafer W110 by screen-printing. Also, although the determination portions 151 are formed on each outer edge of the sealing material 150b, it can be formed only on two edges or three edges of the second plate 120.

### <Alternative 2>

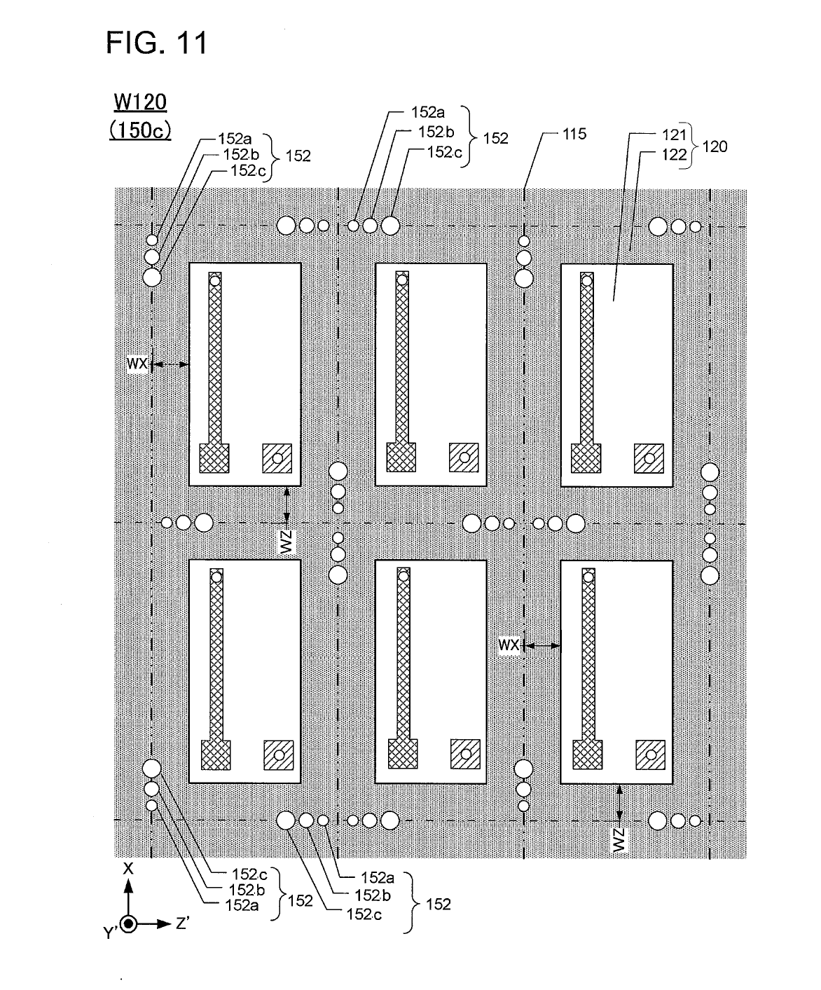

In the second alternative, the sealing material 150c having circular determination portions is explained. FIG. 11 is an enlarged view of the sealing material 150c applied onto the sealing surface 122 of the second wafer W120. As shown, the circular determination portions 152 are formed on each outer edges of the sealing material 150c. The first determination portion 152a, the second determination portion 152b and the third determination portion 152c are formed on each determination portion 152, each determination portion having different width, and so as to extend through the sealing material 150c. Thus, the determination portions 152 are formed so that the sealing surface 122 appears directly. The first determination portion 152a is formed with a predetermined diameter, the second determination portion 152b is formed with a diameter larger than the first diameter, and the third determination portion 152c is formed with a diameter larger than the second diameter. Due to the airtightness, even the third determination portion 152c does not reach to the recess portion 121. Thus, the diameter of the determination portion 152 is smaller than the width WX in the X-axis direction or the width WZ in the Z′-axis direction of the sealing material 150c.

FIG. 11 is one example of the shape of the sealing material 150c applied onto the package, and by forming the determination portions 152 of the sealing material 150c simultaneously with adjacent determination portion 152 of the second plate 120, determination portions 152 can be formed on each edge of the second plate 120. In FIG. 11, the boundary line of the adjacent sealing material 150c is illustrated with two-dot dashed lines. The two-dot dashed lines are also a scribe line 115 that was explained previously. Also, as explained previously, the determination portion 152 can be observed from the top surface of the determination portion 152 during the bonding step or from the side surface of the determination portion 152 after the dicing step. Incidentally, the sealing material 150c can be imprinted on the bonding surface 112 of the first wafer W110, instead of the second wafer W120, by screen-printing. Also, although the determination portions 152 are formed on each outer edge of the sealing material 150c, it can be formed only on two edges or three edges of the second plate 120.

### <Alternative 3>

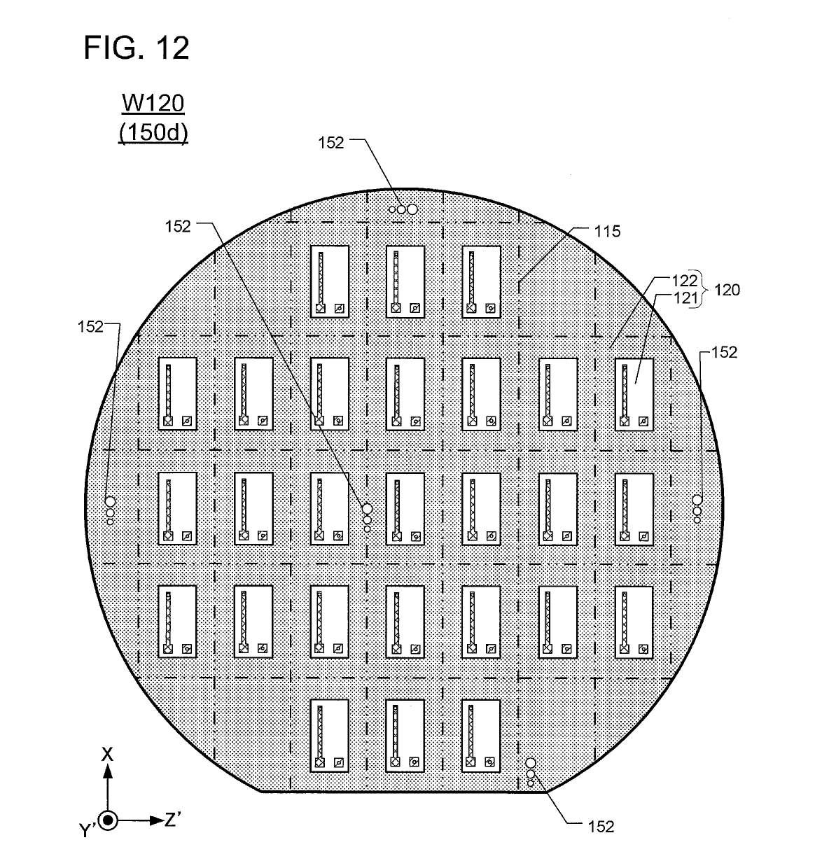

In the third alternative, the determination portions 151, 152 are formed on the major portions of the sealing material 150d. FIG. 12 is an enlarged view of the sealing material 150d applied onto the sealing surface 122 of the second wafer W120. Although the determination portion 152 of FIG. 12 is illustrated in a circular manner, it can be slit-type determination portion 151. As shown, four second determination portions 152 are situated along each outer edge of the second wafer W120, and one second determination portion 152 is situated in the center of the second wafer W120. Four determination portions 152 along the outer edge are formed outside of the second plate 120. The determination portion 152 in the center is formed along the scribe line 115. When the sealing material 150d is screen-printed, the bonding condition of each piezoelectric device 100 cannot be observed after dicing step of step S108. However, as explained in the step S106, by observing the determination portion 152 from top surface (viewed from the first wafer W110), observation can be made to determine whether the plates are appropriately bonded at wafer scale. In the third alternative, it is preferred to form at least one determination portion 152 in the center portion of the second wafer W120.

The determination portion 152 of the above embodiments can be formed on the portions other than along the scribe line 115. Also, although the slit-type determination portion 151 and the circular determination portion 152 are explained in the first embodiment and the alternatives, the determination portions can be in different shapes, such as triangular shape.

Further, in the first embodiment and the alternatives, in order to determine the bonding condition, three different determination portions 152 are formed, namely the first determination portion 152a, the second determination portion 152b and the third determination portion 152c. However, the first determination portion 152a and the third determination portion 152c do not need to be formed. This is because, if the first determination portion 152a is covered and the third determination portion 152c is remaining, it is considered that the plates are appropriately bonded, and by reducing the number of observation, it simplifies the inspection process of the determination portion 152. Further, by forming one first determination portion 151a without forming the second determination portion 152b or the third determination portion 152c on the sealing material 150, the piezoelectric device 100 having defective bonding can be easily selected. Thus, if the first determination portion 152a is covered and cannot be observed, the bonding condition is determined to be appropriate. Furthermore, four determination portions, each having different size, can be formed. This allows more detailed observation of the bonding wafer W100.

The determination portions 151, 152 explained above can be observed during the bonding process, which shows the result of the bonding and acts as a sensor during the bonding process.

### Second Embodiment

In the piezoelectric device of the second embodiment, the piezoelectric vibrating piece thereof comprises a piezoelectric vibrating portion and an outer frame, and the device is formed by placing the outer frame between the first plate and the second plate. Hereinafter, the three-layered piezoelectric device 200 is explained.

### <Configuration of the Piezoelectric Device 200>

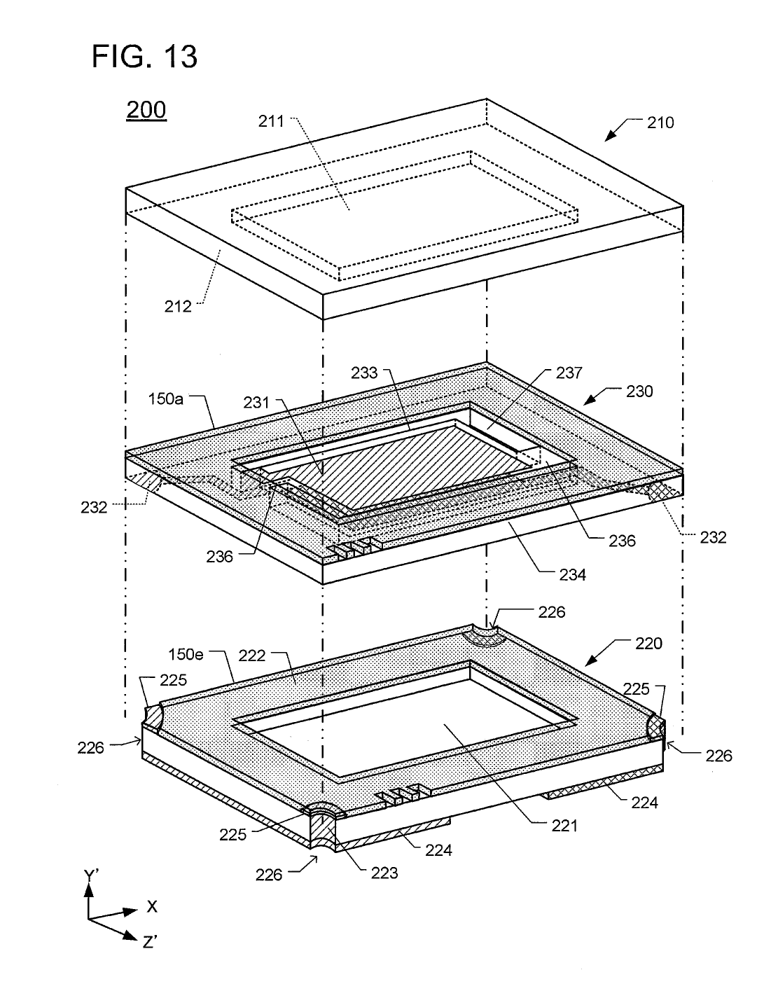

FIG. 13 is an exploded perspective view of the piezoelectric device 200. The piezoelectric device 200 comprises a piezoelectric vibrating piece 230, a first plate (lid) 210 and a second plate (base) 220, and the piezoelectric vibrating piece 230 is placed between the first plate 210 and the third plate 220. Non-electrically conductive insulating material, such as crystal, glass or the like, is used as a material of the first plate 210 and the second plate 220. In addition, an AT-cut crystal vibrating piece is used as the piezoelectric vibrating piece 230, for example. Explanations of the configurations similar to the first embodiment are omitted and same numberings are used for the second embodiment.

The piezoelectric vibrating piece 230 comprises a piezoelectric vibrating portion 233 that vibrates when electrically energized, an outer frame 234 surrounding the piezoelectric vibrating portion 233 and a joining portion 236 for connecting the piezoelectric vibrating portion 233 and the outer frame 234. Between the piezoelectric vibrating piece 233 and the outer frame 234, a through-slot 237 is formed, which extends in the Y′-axis direction of the piezoelectric vibrating piece 230. In the piezoelectric vibrating portion 233, a pair of excitation electrodes 231 are situated on both principal surfaces (+Y′-axis and −Y′-axis surfaces). The extraction electrodes 232 are connected to the excitation electrode 231 formed on the −Y′-axis surface, passes through the joining portion 236 and extracted to the +Z′-axis side and +X-axis corner of the outer frame 234, and connected to the excitation electrode 231 formed on the +Y′-axis surface, passes through the joining portion 236 and extracted to the −Z′-axis side and −X-axis corner of the outer frame 234. The sealing material 150a is applied onto the +Y′-axis surface of the outer frame 234. The sealing material 150a is formed in a predetermined thickness, and the determination portion 151 is formed along one edge of the sealing material 150a. Also, the sealing material 150a in FIG. 13 is a formation before bonding. Also, the sealing material 150a is drawn so as to show the bottom sides of the sealing material 150a in transparent manner.

A recess portion 211 is situated on the −Y′-axis surface of the first plate 210. A bonding surface 212 is formed in periphery of the recess portion 211. The first plate 210 is bonded to the bonding surface 212 via the sealing material 150a applied onto the +Y′-axis surface of the outer frame 234 of the piezoelectric vibrating piece 230.

A recess portion 221 is situated on the +Y′-axis surface of the second plate 220. Also, the bonding surface 222 is formed in periphery of the recess portion 221. A pair of mounting terminals 224 is formed on the −Y′-axis surface of the second plate 220 and the respective conductive pads 225 are formed on each corner of the +Y′-axis surface. On each corner of the second plate 220, the respective castellations 226 are formed along the side surface, and the edge-surface electrodes 223 are formed on the respective castellations 226. The mounting terminals 224 and the conductive pads 225 are electrically connected through the edge-surface electrode 223 situated on the castellation 226. The sealing material 150e is imprinted onto the +Y′-axis surface of the bonding surface 222 by screen-printing. The sealing material 150e is formed in a predetermined thickness, and the determination portion 151 is formed on the outer edge of the sealing material 150e; however, the sealing material 150e is not formed on the conductive pad 225 or the castellation 226. The sealing material 150e illustrated is a shape before bonding together and is drawn with the bottom portion being transparent. The second plate 220 is bonded to the −Y′-axis surface of the outer frame 234 of the piezoelectric vibrating piece 230 through the sealing material 150e applied onto the bonding surface 222. In the determination portion 151 of the sealing material 150e, the first determination portion 151a, the second determination portion 151b and the third determination portion 151c are formed, each having different slits.

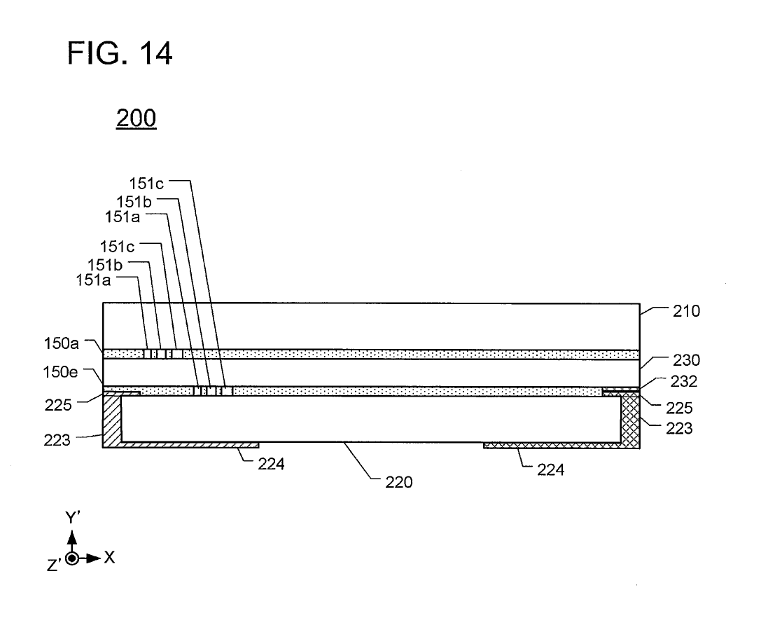

FIG. 14 is a side surface view of the piezoelectric device 200 viewed from the +Z′-axis side. In the piezoelectric device 200, the first plate 210 and the piezoelectric vibrating piece 230 are bonded together using the sealing material 150a, and the second plate 220 and the piezoelectric vibrating piece 230 are bonded together using the sealing material 150e. For the purpose of explanation, FIG. 14 shows the determination portion 151 before melting, thus the first determination portion 151a, the second determination portion 151b and the third determination portion 151c are drawn. Also, as shown in the drawing the determination portion 151 on the sealing material 150a and the determination portion 151 of the sealing material 150e preferably do not overlap with each other. Although the determination portion 151 of the sealing material 150a and 150e are situated on the same edge in this embodiment, it can be situated on different edges.

In the sealing material 150a applied onto the outer frame 234 and the sealing material 150e applied onto the bonding surface 222, the determination portions 151 are formed on one edge out of four edges, and each determination portion have the first determination portion 151a, the second determination portion 151b and the third determination portion 151c along the X-axis direction, each determination portion having different slits. As shown in the first embodiment, the determination portion 151 shows the bonding condition. The bonding condition of the determination portion 151 can be observed while bonding the first plate 210 and the piezoelectric vibrating piece 230, or the second plate 220 and the piezoelectric vibrating piece 230. The shape of the determination portion 151 can have different shapes, or can be the circular determination portion 152.

### <Manufacturing Method of the Piezoelectric Device 200>

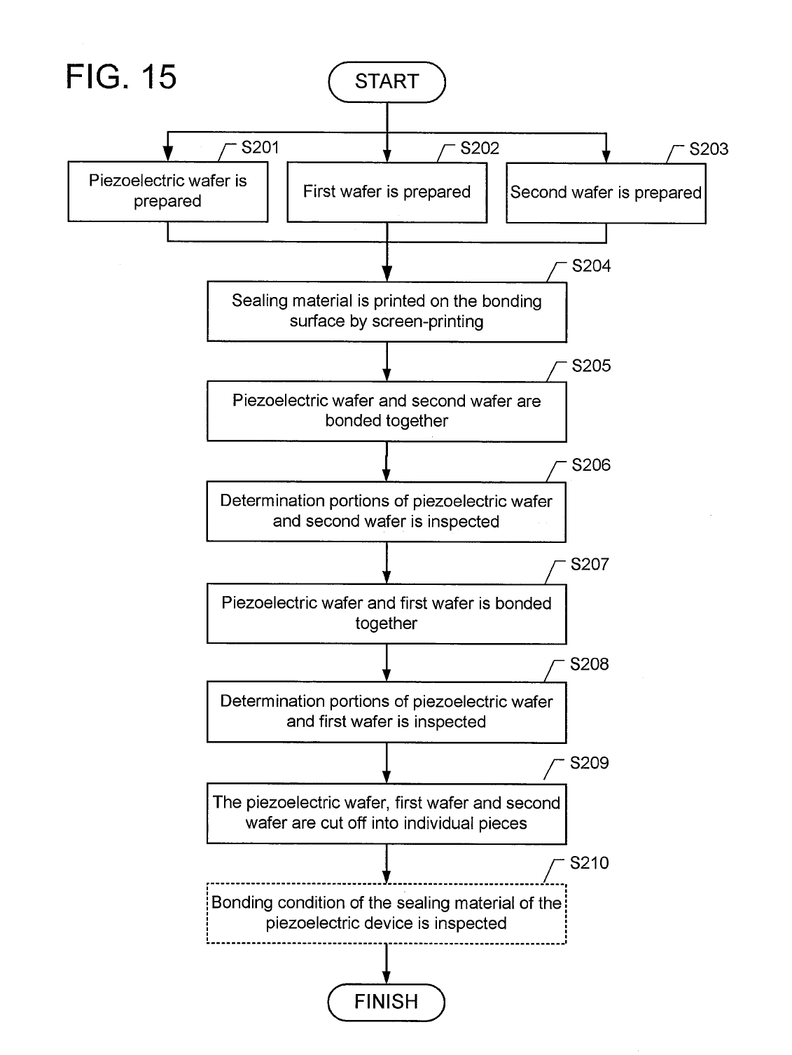

Similar to the piezoelectric device 100, the bonding condition of the sealing material 150a can be preferably observed during the manufacturing process of the piezoelectric device 200. Hereinafter, the manufacturing method of the piezoelectric device 200 is explained using FIGS. 15 to 19 as references.

FIG. 15 is a flow-chart showing the manufacturing step of the piezoelectric device 200.

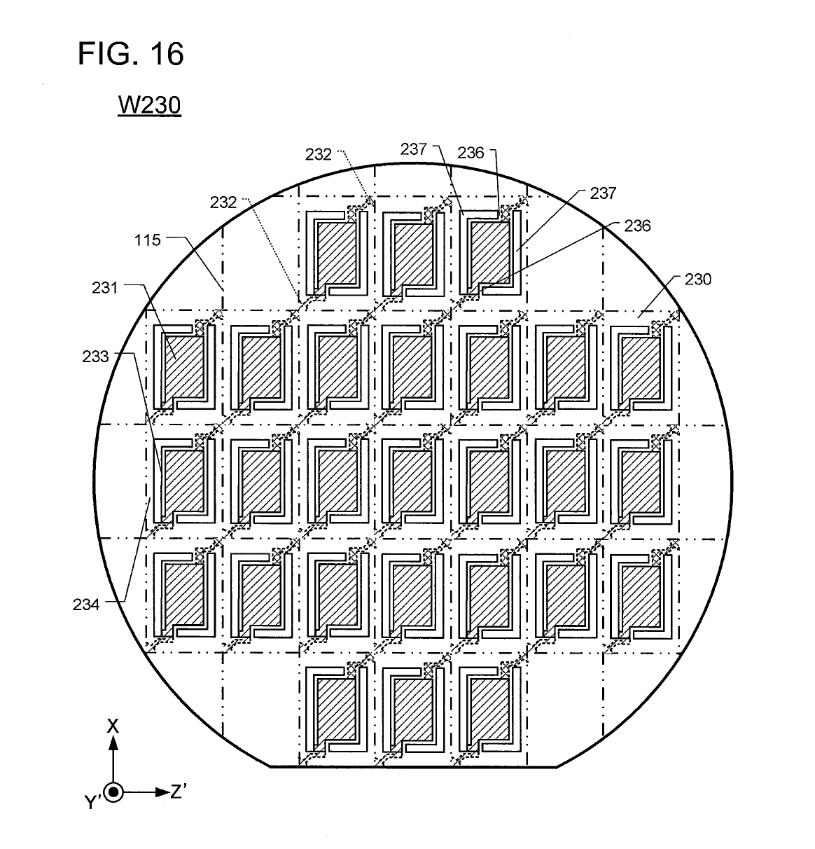

In step S201, the piezoelectric wafer W230 is prepared. In the piezoelectric wafer W230, a plurality of piezoelectric vibrating pieces 230 is formed, and the piezoelectric wafer W230 is formed using the piezoelectric material, such as crystal, as base material. The piezoelectric wafer W230 is explained using FIG. 16 as reference.

FIG. 16 is a plan view of the piezoelectric wafer W230. The piezoelectric wafer W230 comprises a plurality of piezoelectric vibrating pieces 230. In FIG. 16, the scribe lines 115 is drawn with two-dot dashed lines for cutting the wafer in the step S210, and one piezoelectric vibrating piece 230 is formed within the region surrounded by the scribe line 115. On each piezoelectric vibrating piece 230 of the piezoelectric wafer W230, the piezoelectric vibrating portion 233, the outer frame 234 and the joining portion 236 are formed simultaneously with formation of the through-slit 237. Also, the excitation electrodes 231 are formed on the piezoelectric vibrating portion 233, and the extraction electrode 232 are formed from the excitation electrode 231 along the joining portion 236.

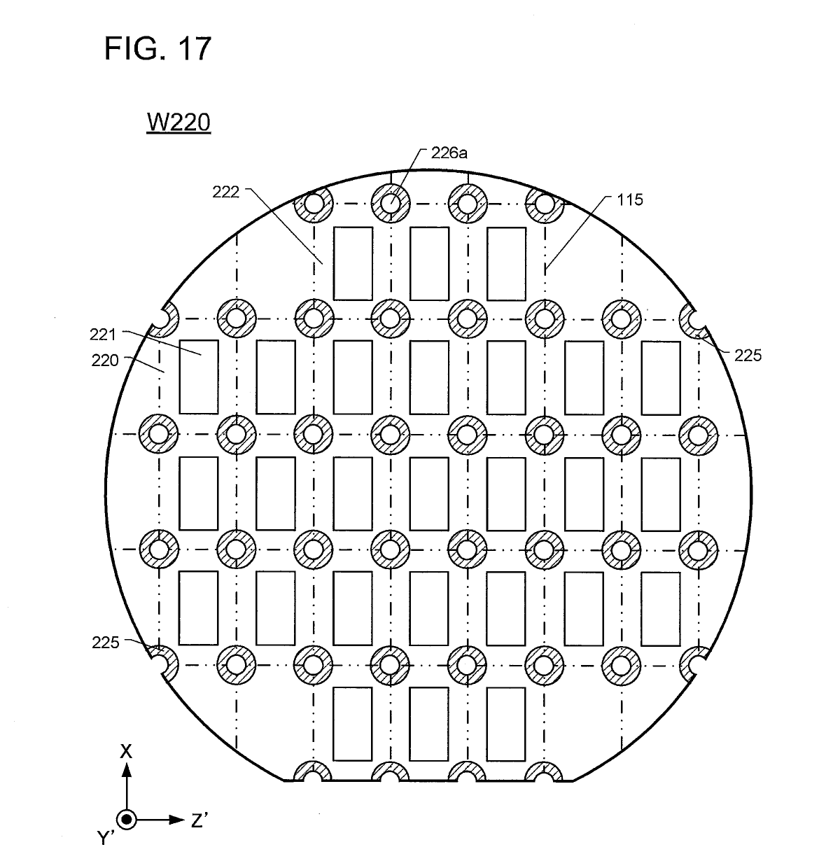

In step S202, the second wafer W220 is prepared. The plurality of second plates 220 is formed on the second wafer W220. The second wafer W220 is formed by crystal or glass, for example. The second wafer W220 is explained using FIG. 17 as a reference.

FIG. 17 is a plan view of the second wafer W220. On the second wafer W220, a plurality of second plates 220 are formed. In FIG. 17, the scribe lines 115 are drawn as two-dot dashed lines and a region surrounded by the scribe line 115 forms one second plate 220. A recess 221 is formed on the +Y′-axis surface of each second plate 220, and the bonding surface 222 is situated in periphery of the recess portion 221. A through-slot 226a is formed on the intersection between the scribe line 115 in the Z′-axis direction and the scribe line 115 in the X-axis direction. The through-slot 226a forms one castellation 226 in the second plate 220, and the edge-surface electrode 223 (see FIGS. 13, 14) is formed on each castellation 226. Surrounding the through-slot 226a, a conductive pad 225 is formed, and the mounting terminal 224 (see FIGS. 13, 14) are formed on the −Y′-axis surface of the second wafer W220.

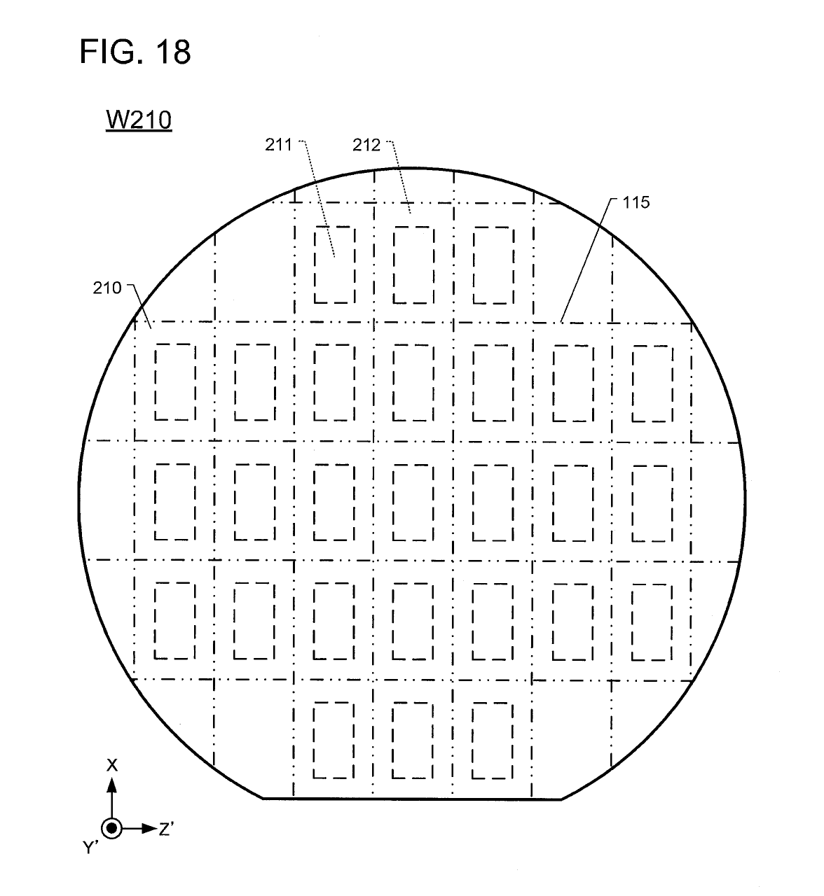

In step S203, a first wafer W210 is prepared. The plurality of first plates 210 is formed on the first wafer W210. The first wafer W210 is formed by crystal or glass, for example. The first wafer W210 is explained using FIG. 18 a as reference.

FIG. 18 is a plan view of the second wafer W210. A plurality of first plates 210 are formed on the first wafer W210. In FIG. 18, the scribe lines 115 is drawn with two-dot dashed lines, and one piezoelectric vibrating piece 210 is formed within the region surrounded by the scribe line 115. A recess 221 is formed on the −Y′-axis surface of each first plate 210, and the bonding surface 212 is situated in periphery of the recess portion 211. The steps S201 to S203 can be performed in any order.

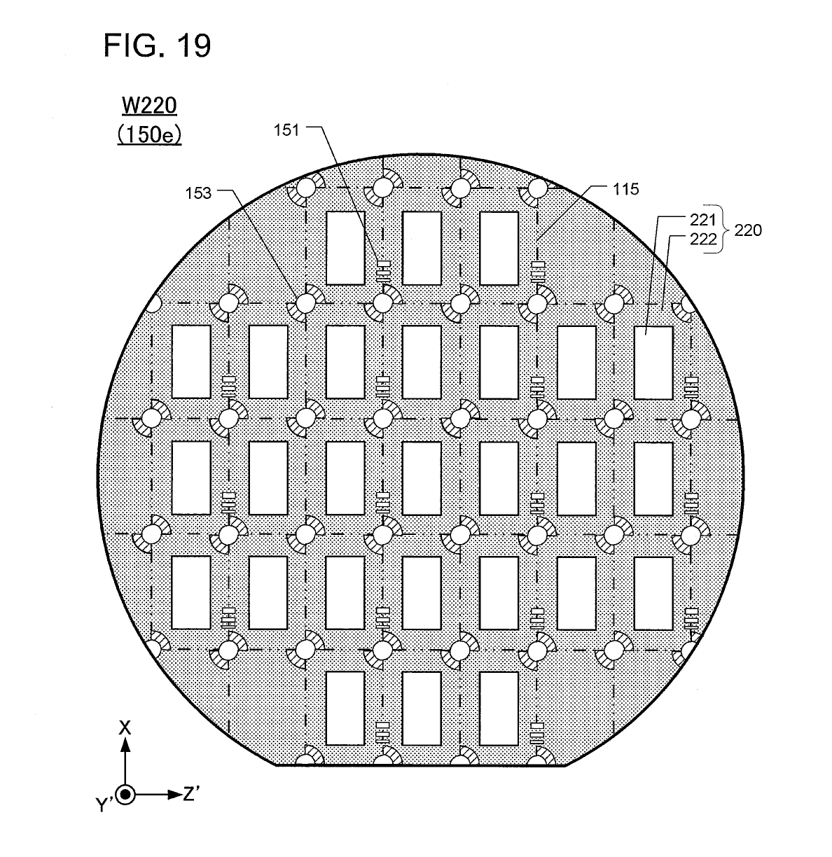

In step S204, the sealing material 150e is screen-printed onto the second wafer W220. FIG. 19 is a plan view of the screen-printed sealing material 150e. The sealing material 150e is applied onto the bonding surface 222 of the second wafer W220. On the sealing material 150e, three slits of determination portions 151 are formed on one edge out of four edges of the second plate 220, each slit having different width. Also, in the sealing material 150e, the non-sealing-application region 153 is formed in periphery of the through-slot 226a for forming the castellation 226 on the second wafer W220 and on a part of the conductive pad 225, in which the sealing material 150e is not formed. Incidentally, the sealing material 150e can be applied onto the outer frame 234 of the piezoelectric vibrating piece 230 on the −Y′-axis surface. The sealing material 150a is screen-printed on the piezoelectric vibrating piece 230. The sealing material 150a is printed with the shape as described in FIG. 6, for example. The sealing material 150a is applied on to the outer frame 234 situated on the +Y′-axis surface of the piezoelectric vibrating piece 230. On the sealing material 150a, three slits of determination portions 151 are formed on one edge out of four edges of the second plate 220, each slit having different width. The sealing material 150a can be applied onto the bonding surface 212 of the first wafer W210 in the −Y′-axis direction. Also, the determination portion 151 is preferably formed in a different position from the position formed previously in step S204. If the screen-printed sealing material 150e is low-melting point glass, for example, the low-melting point glass includes the glass element, binder and solvent. The low-melting point glass is heated until reaches to the evaporation temperature that the binder or solvent evaporates, and then preliminary cured.

In step S205, the piezoelectric wafer W230 and the second wafer W220 are bonded together via the sealing material 150e. The piezoelectric wafer W230 and the second wafer W220 are bonded together by pressurizing and heating and by using the sealing material 150e.

In step S206, the shape of the determination portions 151 of the sealing material 150e is inspected during the observation step. Since the piezoelectric wafer W230 and the second wafer W220 are fabricated by using transparent materials such as crystal, the bonding condition of the sealing material 150e can be observed by observing the bonded piezoelectric wafer W230 and the second wafer W220 from the +Y′-axis surface. The bonding condition can be observed visually or by using the imaging element 170. Particularly, by using the imaging element 170, the bonding condition can be observed by focusing the position of the determination portion 151 formed during the step S204. Also, a visual observation or use of the imaging element 170 not only allows to observe the shape of the determination portion 151, but also allows to detect any foreign object or defective bonding between the outer frame 234 of the piezoelectric wafer W230 and the bonding surface 222 of the second wafer W220.

In step S207, the piezoelectric wafer W230 and the first wafer W210 are bonded together via the sealing material 150a. The first wafer W210 is mounted onto the outer frame 234 of the piezoelectric vibrating piece 230, which the sealing material is applied during the step S207, and bonded together by pressing and heating. The first wafer W210, the second wafer W220 and the piezoelectric wafer W230 are stacked together, thus forming the bonded wafer.

In step S208, the shape of the determination portion 151 of the sealing material 150a is inspected during the observation step. Since the first wafer W210, the second wafer W220 and the piezoelectric wafer W230 are fabricated using transparent materials such as crystal, the bonding condition of the determination portion 151 of the sealing material 150a can be visually observed when viewed from the +Y′-axis surface. The bonding condition can be observed visually or by using the imaging element 170. Particularly, by using the imaging element 170, the bonding condition can be observed by matching the position of the determination portion 151 formed during the step S208.

In step S109, the bonded first wafer W210, the second wafer W220 and the piezoelectric wafer W230 is cut into separate pieces. The cut is made along the scribe line 115, and thus forms individual piezoelectric devices 200.

In step S210, the bonding condition of the separated piezoelectric device 200 is inspected on a necessary basis. The bonding condition is inspected by detecting the chipping or bending of the piezoelectric device 200 during the dicing step in step S209. Incidentally, since the sealing material 150a is semi-transparent, the observation can be made from the +Y′-axis direction using the imaging element 170 by adjusting the focus to the sealing material 150a or to the sealing material 150b.

In step S205 of the flow-chart, the piezoelectric wafer W230 and the second wafer W220 are bonded together in step S205, and the piezoelectric wafer W230 and the first wafer W210 are bonded together in step S207. However, the piezoelectric wafer W230 and the first wafer W210 can be bonded first, or the first wafer W210, the piezoelectric wafer W230 and the second wafer W220 can be bonded simultaneously with each other.

As mentioned above, although optimal embodiments of the present disclosure were explained in detail, it will be understood by a person skilled in the art that the disclosure encompasses various alterations and modifications to the embodiments, within the technical scope of the disclosure.

For example, although embodiments were explained using an AT-cut quartz-crystal material as an example of the piezoelectric vibrating piece, it will be understood that the embodiments can be applied with equal facility to BT-cut piezoelectric material that vibrates in a thickness-shear mode. Also, the embodiments can be applied with equal facility to tuning-fork type quartz-crystal vibrating piece. Further, the piezoelectric vibrating piece can be made with equal facility of other piezoelectric materials such as lithium tantalite, lithium niobate, and piezoelectric materials comprising the piezoelectric ceramics.

What is claimed is:

1. A piezoelectric device, comprising:
a piezoelectric vibrating piece that vibrates when being electrically energized;
a first plate and a second plate fabricated by transparent materials and storing the piezoelectric vibrating piece;
a sealing material having a predetermined width and a frame shape, and configured at a peripheral of and between the first plate and the second plate for sealing the first plate and the second plate; and
a slit configured in the sealing material, the slit extending along a direction of the predetermined width without completely cutting through the sealing material along the direction of the predetermined width.

2. A piezoelectric device, comprising:
a piezoelectric vibrating piece including a piezoelectric vibrating portion that vibrates when being electrically energized and an outer frame surrounding the piezoelectric vibrating portion;
a first plate fabricated by transparent materials and bonded to a principal surface of the outer frame of the piezoelectric vibrating piece; and
a first sealing material having a frame shape and a predetermined width, and configured at a periphery of and between the first plate and the outer frame, and sealing the first plate and the outer frame;
a slit configured in the sealing material that bonds the first plate and the outer frame, the slit extending along a direction of the predetermined width without completely cutting through the sealing material along the direction of the predetermined width.

3. The piezoelectric device of claim 2, further comprising:
a second plate fabricated by the transparent materials and bonded to another principal surface of the outer frame of the piezoelectric vibrating piece;
a second sealing material having a frame shape and a predetermined width, and configured at a periphery of and between the second plate and the outer frame, and sealing the second plate and the outer frame; and
a slit configured in the second sealing material that bonds the second plate and the outer frame, the slit extending along a direction of the predetermined width without completely cutting through the second sealing material along the direction of the predetermined width.

4. The piezoelectric device of claim 1, wherein the first sealing material is a low-melting-point glass or polyimide resin that melts between 350° C. to 410° C.

5. A method for manufacturing a piezoelectric device of claim 1, the method comprising the steps of:
preparing a piezoelectric vibrating piece that vibrates when being electrically energized;
preparing a first plate and a second plate fabricated by transparent materials;
applying a sealing material in periphery of the first plate and the second plate in a frame shape having predetermined width, the sealing material having a slit that does not extend through the predetermined width;
after the applying step, bonding the first plate and the second plate together using the sealing material; and
after the bonding step, inspecting the slit by observing the first plate or the second plate.

6. The method for manufacturing the piezoelectric device of claim 5, wherein;
the step of preparing the first plate and the second plate includes a step of preparing a first wafer having a plurality of first plates and a second wafer having a plurality of second plates; and
the step of bonding includes a bonding of the first wafer and the second wafer.

7. A method for manufacturing a piezoelectric device of claim 2, the method comprising the steps of:
preparing a piezoelectric vibrating piece having a piezoelectric vibrating portion that vibrates when being electrically energized and an outer frame surrounding the piezoelectric vibrating portion;
preparing a first plate fabricated by transparent materials;
applying a first sealing material in periphery of the first plate or the outer frame in a frame shape having predetermined width, the first sealing material having a slit that does not extend through the predetermined width;
after the applying step, bonding a principal surface of the outer frame and the first plate together using the first sealing material; and
after the bonding step, inspecting the slit by observing the first plate or the outer frame.

8. The method for manufacturing a piezoelectric device of claim 7, wherein:
the step of preparing the piezoelectric vibrating piece includes a step of preparing a piezoelectric wafer having a plurality of piezoelectric vibrating pieces;
the step of preparing the first plate includes a step of preparing a first wafer having a plurality of first plates; and
the step of bonding includes the bonding of the piezoelectric wafer and the first wafer.

9. The method for manufacturing a piezoelectric device of claim 5, wherein the applying step includes applying of a sealing material having the plurality of slits, each slit having different width; and
wherein the inspecting step includes inspecting of the plurality of slits after being pressed and covered during the bonding step.

10. The method for manufacturing a piezoelectric device of claim 5, wherein the applying step includes applying of a sealing material having the plurality of slits, each slit having same width; and
wherein the inspecting step includes inspecting of the plurality of slits after being pressed and covered during the bonding step.

11. The method for manufacturing a piezoelectric device of claim 5, wherein the applying step applies a sealing material having the at least one slit to each piezoelectric device; and
wherein the inspecting step includes inspecting of the plurality of slits after being pressed and covered during the bonding step.

12. The method for manufacturing a piezoelectric device of claim 5, wherein the inspecting step includes the inspecting of the plurality of slits after being pressed and covered during the bonding step and comparing with remaining slit by using an imaging element.

13. The method for manufacturing a piezoelectric device of claim 5, wherein the slit is formed on at least a portion of the sealing material having the frame shape, the frame shape having four edges and in a predetermined width.
